(19) United States
(12) Patent Application Publication
(10) Pub. No.: US 2008/0296716 A1
(43) Pub. Date: Dec. 4, 2008

(54) Sensor semiconductor device and manufacturing method thereof

(75) Inventors: Chang-Yueh Chan, Taichung (TW); Chien-Ping Huang, Taichung (TW); Chih-Ming Huang, Hsinchu Hsein (TW); Cheng-Hsu Hsiao, Taichung (TW); Chun-Chi Ke, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/151,570

(22) Filed: May 7, 2008

(30) Foreign Application Priority Data
May 7, 2007 (TW) 096116053

(51) Int. Cl. H01L 21/50; H01L 23/00

(52) U.S. Cl. 257/433; 438/64; 257/E21.499; 257/E23.001

(57) ABSTRACT

A sensor semiconductor device and a manufacturing method thereof are disclosed. The method includes: providing a light-permeable carrier board with a plurality of metallic circuits; electrically connecting the metallic circuits to a plurality of sensor chips through conductive bumps formed on the bond pads of the sensor chips, wherein the sensor chips have been previously subjected to thinning and chip probing; filling a first dielectric layer between the sensor chips to cover the metallic circuits and peripheries of the sensor chips; forming a second dielectric layer on the sensor chips and the first dielectric layer; forming grooves between the sensor chips for exposing the metallic circuits such that a plurality of conductive traces electrically connected to the metallic circuits can be formed on the second dielectric layer; and singulating the sensor chips to form a plurality of sensor semiconductor devices. The present invention overcomes the drawbacks of breakage of trace connection due to a sharp angle formed at joints, poor electrical connection and chip damage due to an alignment error in cutting from the back of the wafer, as well as an increased cost due to multiple sputtering processes for forming traces.

### BACKGROUND OF THE INVENTION

1. Field of the Invention

The present invention relates to sensor semiconductor devices and manufacturing methods thereof, and more particularly, to a wafer-level chip-scale packaged (WLCSP) sensor semiconductor device and a manufacturing method thereof.

2. Description of the Prior Art

To manufacture a conventional image sensor package involves mounting a sensor chip on a chip carrier, electrically connecting the sensor chip and the chip carrier through bonding wires, and covering the upper surface of the sensor chip with a glass so as to allow image lights to be captured by the sensor chip. Afterward, the fully packaged image sensor package is integrated into an external device such as a printed circuit board (PCB) for use in digital still cameras (DSC), digital video cameras (DV), optical mice, cellular phones, etc.

Owing to ever-increasing information transmission capacity and trends of miniaturization and portability in electronic products, more attention is focused on integrated circuits with high input/out (I/O) counts, efficient heat dissipation and small size, and integrated circuit packages are developed towards small size and high electrical performance. Accordingly, the semiconductor industry developed WLSCP sensor semiconductor devices with a size slightly larger than the sensor chip integrated therein, thereby allowing the WLSCP sensor semiconductor devices to be effectively applied to small-sized electronic products.

Referring to FIGS. 1A to 1H, which are schematic views showing a sensor semiconductor device and a manufacturing method thereof as disclosed in U.S. Pat. No. 6,777,767. The manufacturing method of the sensor semiconductor device comprises: providing a wafer 10A having a plurality of sensor chips 10, wherein extension traces 11 are formed between bond pads 101 of adjacent sensor chips 10 by sputtering (as shown in FIG. 1A); adhering a glass 12 on the extension traces 11 through an adhesive layer 13 (as shown in FIG. 1B); thinning the back of the wafer 10A by grinding (as shown in FIG. 1C); cutting the back of the wafer 10A between adjacent sensor chips 10 using a cutting tool and then etching along the cutting positions by plasma etching so as to expose the extension traces 11 (as shown in FIG. 1D); adhering another glass 15 and a dielectric layer 16 to the back of the wafer 10A through an adhesive 14 (as shown in FIG. 1E); cutting through the extension traces 11 from the back of the wafer 10A so as to form slanted grooves 17 (as shown in FIG. 1F); forming metal routing traces 18 on the slanted grooves 17 and a portion of the dielectric layer 16 around the slanted grooves 17 by sputtering, the metal routing traces 18 electrically connecting the extension traces 11 (as shown in FIG. 1G); and mounting solder balls 19 to the metal routing traces 18, and singulating the sensor chips 10 so as to obtain a plurality of WLCSP sensor semiconductor devices (as shown in FIG. 1H).

However, as sides of the sensor semiconductor devices are slanted after the singulation process owing to the slanted grooves formed on the back of the wafer, that is, the vertical cross-section of the sensor semiconductor devices is an inverted trapezoid, with its planar width decreasing downward, an acute angle is formed at joints of the metal routing traces and the extension traces, which can easily cause stresses to be concentrated at the joints, thereby resulting in breakage of the trace connections between the metal routing traces and the extension traces. Moreover, due to the alignment error, the slanted grooves formed in the back of the wafer may deviate from the predetermined positions, thus resulting a poor electrical connection between the metal routing traces and the extension traces and even damaging the chips.

In addition, forming the extension traces and the metal routing traces respectively through a sputtering process requires a high manufacturing cost.

Moreover, during the thinning process of the wafer that has been previously adhered to the glass, since the adhesive layer is not disposed between the centrally located sensing areas of the sensor chips and the glass, that is, the sensor chips lack support from the glass, the sensor chips crack easily due to grinding-induced stress. Therefore, the minimum thickness of the wafer after the thinning process is 150 μm.

Besides, the process is directly performed on the wafer without taking account of qualities of dies, in other words, the process continues despite bad dies of the wafer, thus resulting in a waste of material and an increase of cost.

Accordingly, it has become urgent to develop a sensor semiconductor device and a manufacturing method thereof so as to overcome the above-described drawbacks.

### SUMMARY OF THE INVENTION

In light of the aforesaid drawbacks of the prior art, it is an object of the present invention to provide a sensor semiconductor device and a manufacturing method thereof so as to prevent breakage of trace connections from occurring due to a sharp angle formed at joints.

Another object of the present invention is to provide a sensor semiconductor device and a manufacturing method thereof so as to prevent poor electrical connection of traces and chip damage which might otherwise occur because of an alignment error in cutting a wafer from the back thereof.

Yet another object of the present invention is to provide a sensor semiconductor device and a manufacturing method thereof so as to prevent multiple sputtering processes for forming traces that lead to a high manufacturing cost.

A further object of the present invention is to provide a sensor semiconductor device and a manufacturing method thereof so as to prevent chip damage resulted from a conventional thinning process of the wafer.

A further object of the present invention is to provide a sensor semiconductor device and a manufacturing method thereof so as to ensure that chips in use are good.

In order to achieve the above and other objects, the present invention discloses a manufacturing method of a sensor semiconductor device, which comprises: providing a light-permeable carrier board and a plurality of sensor chips, wherein the light-permeable carrier board has a plurality of metallic circuits formed thereon, the sensor chips each have an active surface and a non-active surface opposed to the active surface, the active surface has a sensing area disposed thereon and a plurality of bond pads disposed around the sensing area, and conductive bumps are formed on the bond pads such that the sensor chips are mounted on and electrically connected to the metallic circuits of the light-permeable carrier board via the conductive bumps; filling a first dielectric layer between the sensor chips on the light-permeable carrier board so as to cover peripheries of the sensor chips and the metallic circuits; covering the sensor chips and the first dielectric layer with a second dielectric layer, and forming grooves in the first and second dielectric layers between the sensor chips for exposing the metallic circuits on the light-permeable carrier board; forming a plurality of conductive traces on the second dielectric layer, and electrically connecting the conductive traces to the metallic circuits exposed from the first and second dielectric layers; and singulating the sensor chips so as to form a plurality of sensor semiconductor devices.

Another preferred embodiment of the manufacturing method of the present invention comprises forming a dielectric layer on the light-permeable carrier board to cover the sensor chips and metallic circuits, thus dispensing with the process of forming a second dielectric layer.

The manufacturing method further comprises: forming a solder mask layer on the second dielectric layer and conductive traces and forming openings in the solder mask layer for exposing a portion of the conductive traces, and mounting conductive elements on the exposed conductive traces. A reinforcing element such as a dummy die and a glass can further be adhered to the solder mask layer so as to reinforce the sensor semiconductor devices. Alternatively, a reinforcing element such as a dummy die and a glass can further be adhered between the second dielectric layer and the sensor chips as well as the first dielectric layer so as to reinforce the sensor semiconductor devices. Thereafter, grooves are formed between the sensor chips to expose the metallic circuits on the light-permeable carrier board, and conductive traces electrical connecting the metallic circuits are formed on the second dielectric layer.

The manufacturing method further comprises forming a buffer layer between the light-permeable carrier board and the metallic circuits so as to alleviate the stress of the metallic circuits.

Therein, the process for manufacturing the sensor chips comprises: providing a wafer having a plurality of sensor chips, wherein the wafer and sensor chips each have an active surface and a non-active surface opposed to the non-active surface, the active surface of each of the sensor chips has a sensing area and a plurality of bond pads; after selecting good dies from the sensor chips by chip probing (CP), mounting conductive bumps on the bond pads of the good dies; and thinning the non-active surface of the wafer and singulating the sensor chips so as to form plurality of sensor chips with conductive bumps.

Through the aforesaid manufacturing method, the present invention further discloses a sensor semiconductor device, comprising: a light-permeable carrier board; metallic circuits formed on edges of the light-permeable carrier board; a sensor chip having an active surface and a non-active surface opposed to the active surface, wherein the active surface is formed with a sensing area and a plurality of bond pads, and conductive bumps are formed on the bond pads such that the sensor chip can be mounted on the metallic circuits via the conductive bumps; a first dielectric layer covering periphery of the sensor chip; a second dielectric layer covering the non-active surface of the sensor chip; and conductive traces formed on the first and second dielectric layers and electrically connected to the metallic circuits.

The sensor semiconductor device further comprises: a solder mask layer formed on the second dielectric layer and the conductive traces, wherein openings are formed in the solder mask layer for exposing a portion of the conductive traces; and conductive elements mounted on the exposed conductive traces. A reinforcing element such as a dummy die or a glass is further adhered to the solder mask layer so as to reinforce the sensor semiconductor device.

Alternatively, a reinforcing element such as a dummy die or a glass is adhered between the second dielectric layer and the sensor chips as well as the first dielectric layer so as to reinforce the sensor semiconductor device. A buffer layer is further formed between the light-permeable carrier board and the metallic circuits to alleviate the stress of the metallic circuits.

Another preferred embodiment of a sensor semiconductor device of the present invention comprises: a light-permeable carrier board; metallic circuits formed on edges of the light-permeable carrier board; a sensor chip having an active surface and a non-active surface opposed to the active surface, wherein the active surface is formed with a sensing area and a plurality of bond pads, and conductive bumps are formed on the bond pads such that the sensor chip is mounted on the metallic circuits via the conductive bumps; a dielectric layer covering the sides and non-active surface of the sensor chip; and conductive traces formed on the dielectric layer and electrically connected to the metallic circuits.

Therefore, the present invention mainly comprises: providing a light-permeable carrier board with a plurality of metallic circuits and providing a plurality of sensor chips with bond pads, wherein conductive bumps are formed on the bond ponds, and the sensor chips are pre-thinned and are pre-determined as good dies by chip probing (CP) so as to prevent chip damage caused by the conventional thinning process and allow the wafer to become thinner and meanwhile ensure the sensor chips in use are good dies, the sensor chips being electrically connected to the metallic circuits of the light-permeable carrier board via the conductive bumps; forming a first dielectric layer between the sensor chips on the light-permeable carrier board to cover peripheries of the sensor chips, forming a second dielectric layer to cover the sensor chips and the first dielectric layer, and forming grooves in the first and second dielectric layers for exposing the metallic circuits on the light-permeable carrier board, and forming on the second dielectric layer a plurality of conductive traces electrical connecting the metallic circuits, or, alternatively, forming a dielectric layer on the light-permeable carrier board so as to dispense with the process of forming a second dielectric layer, the dielectric layer covering the sensor chips and metallic circuits and being filled between the sensor chips, and forming grooves in the dielectric layer to expose the metallic circuits on the light-permeable carrier board, and forming on the dielectric layer a plurality of conductive traces for electrical connecting with the metallic circuits; disposing a solder mask layer and conductive elements on the dielectric layer, and singualting the sensor chips so as to form a plurality of sensor semiconductor devices. The present invention prevents breakage of trace connections due to a sharp angle formed at joints and overcomes poor electrical connection of traces and chip damage due to an alignment error in cutting a wafer from the back thereof, and also overcomes high fabrication cost caused by multiple sputtering processes for forming traces in the prior art.

### BRIEF DESCRIPTION OF THE DRAWINGS

FIGS. 1A to 1H (PRIOR ART) are schematic views showing a sensor semiconductor device and a manufacturing method thereof disclosed in U.S. Pat. No. 6,777,767;

FIGS. 2A to 2K are schematic views showing a first preferred embodiment of a sensor semiconductor device and a manufacturing method thereof in accordance with the present invention;

FIGS. 3A to 3D are schematic views showing a second preferred embodiment of a sensor semiconductor device and a manufacturing method thereof in accordance with the present invention;

FIG. 4 is a schematic view showing a third preferred embodiment of a sensor semiconductor device and a manufacturing method thereof in accordance with the present invention;

FIG. 5 is a schematic view showing a fourth preferred embodiment of a sensor semiconductor device and a manufacturing method thereof in accordance with the present invention;

FIG. 6 is a schematic view showing a fifth preferred embodiment of a sensor semiconductor device and a manufacturing method thereof in accordance with the present invention; and

FIGS. 7A and 7B are schematic views showing a sixth preferred embodiment of a sensor semiconductor device and a manufacturing method thereof in accordance with the present invention.

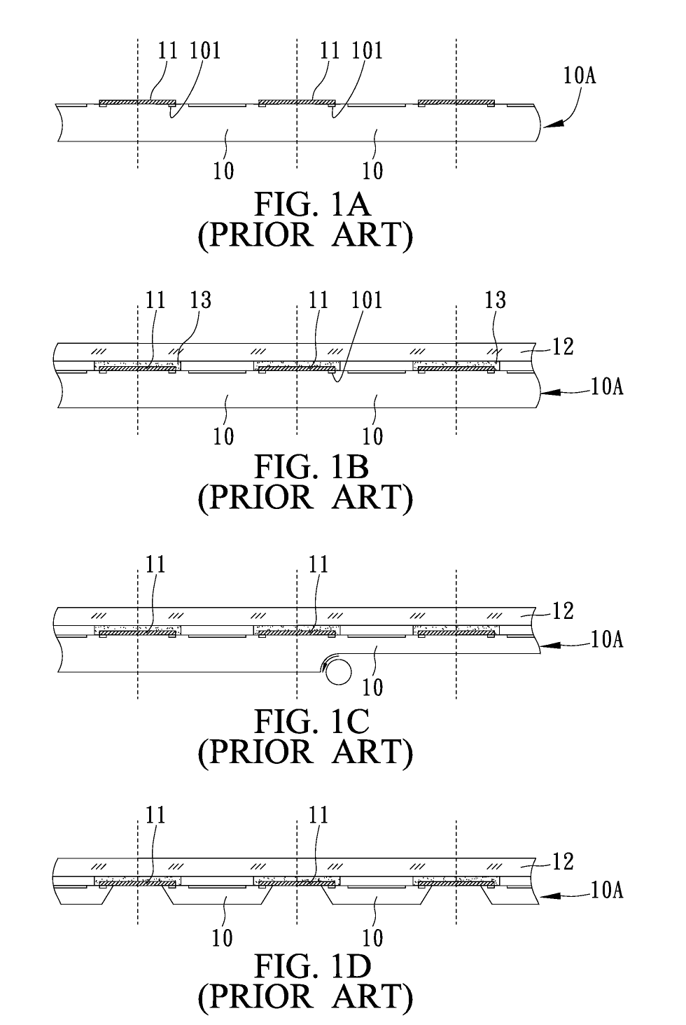

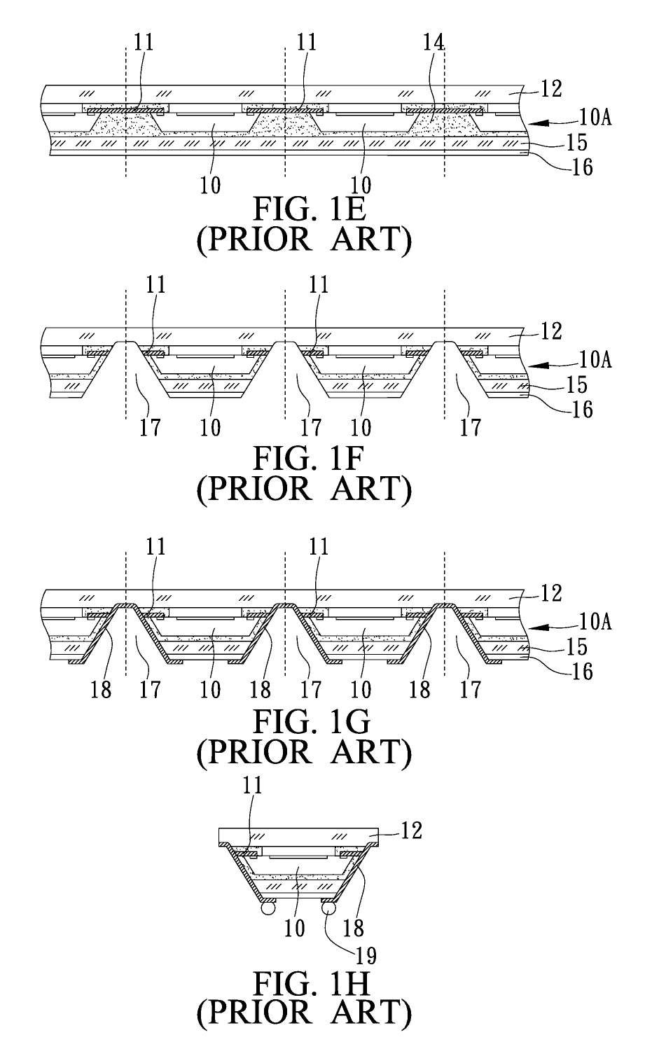

### DETAILED DESCRIPTION OF THE PREFERRED EMBODIMENTS

The following specific embodiments are provided to illustrate the present invention. Persons skilled in the art can readily gain insight into other advantages and features of the present invention based on the contents disclosed in this specification.

### First Preferred Embodiment

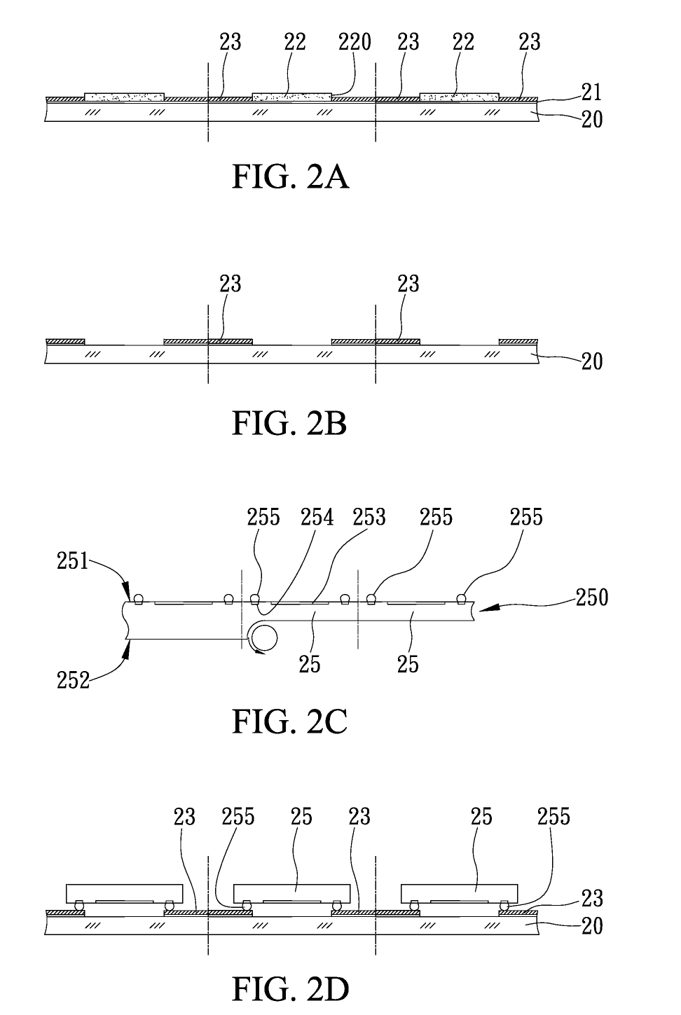

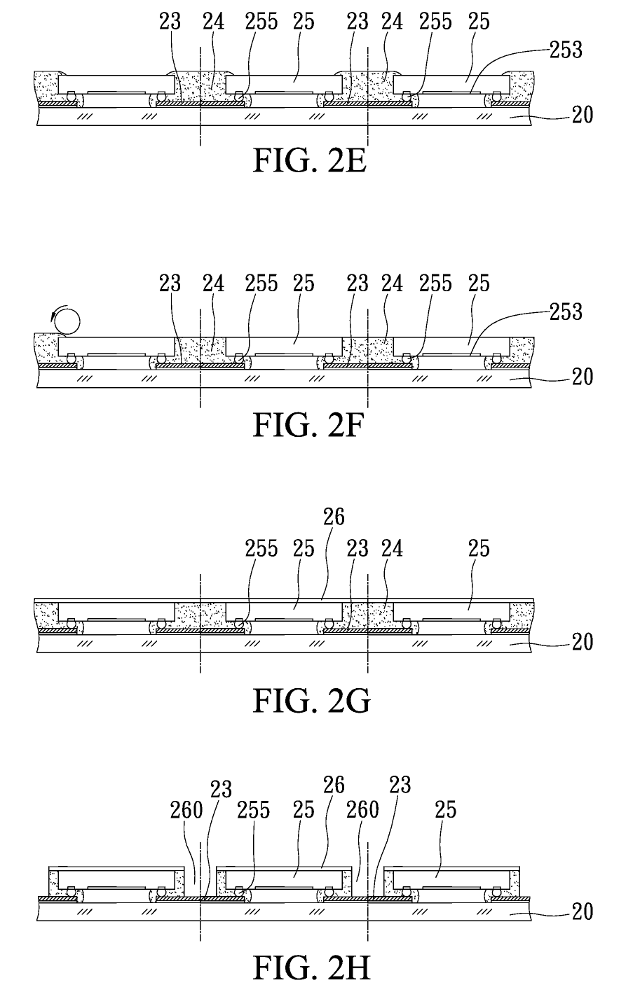

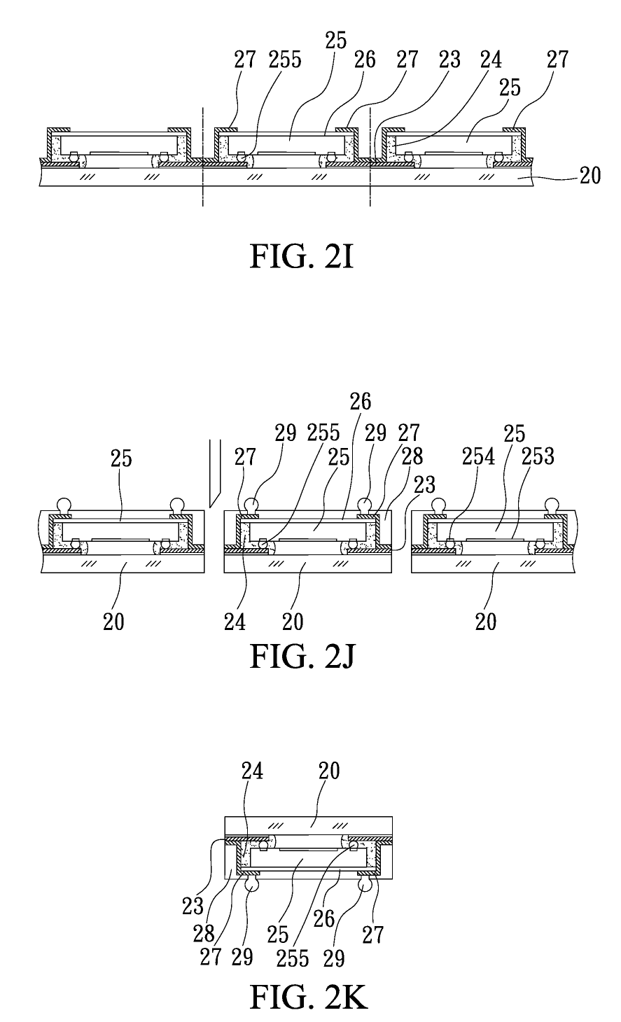

FIGS. 2A to 2K are schematic views showing the first preferred embodiment of a sensor semiconductor device and a manufacturing method thereof in accordance with the present invention.

Referring to FIG. 2A, a light-permeable carrier board 20 such as glass is provided. A thin conductive layer 21 made of such as TiW/Cu or Ti/NiV is formed on the light-permeable carrier board 20 by sputtering. A resist layer 22 is formed on the thin conductive layer 21, and a plurality of openings 220 is formed in the resist layer 22 to expose a portion of the thin conductive layer 21 such that metallic circuits 23 can be formed on the exposed thin conductive layer 21 in the openings 220 by electroplating. The metallic circuits 23 may be made of Cu/Ni, Cu/Sn, or Cu/Ni/Solder, which have a thickness of approximately 3-10 μm.

Referring to FIG. 2B, the resist layer 22 and the thin conductive layer 21 covered by the resist layer 22 are removed.

Therein, the light-permeable carrier board 20 is divided into a plurality of carrier board units corresponding to sensor semiconductor devices to be formed later so as to allow image lights to be captured by sensor chips of the sensor semiconductor devices, and the plurality of metallic circuits 23 is formed between adjacent carrier board units.

Referring to FIG. 2C, a wafer 250 with a plurality of sensor chips 25 is provided. The wafer 250 and sensor chips 25 each have an active surface 251 and a non-active surface 252 opposed to the active surface 251. A sensing area 253 is formed on the active surface 251 of each of the sensor chips 25 and a plurality of bond pads 254 is formed around the sensing area 253. A chip probing process is performed to determine good dies so as to mount conductive bumps 255 such as Au Stud bumps, Au bumps or solder bumps on the bond pads 254 of the good dies. Then, the non-active surface 252 of the wafer 250 is thinned, and the sensor chips 25 are singulated.

Compared with the prior art (e.g. U.S. Pat. No. 6,777,767) that can lead to chip damage during a wafer thinning process and thus prevent further thinning of the wafer, the present invention performs a thinning process directly on the wafer without causing chip damage and thus allow the wafer to be thinned to a thickness of 50-100 μm.

Referring to FIG. 2D, good dies of the sensor chips 25 are mounted on and electrically connected to the metallic circuits 23 of the light-permeable carrier board 20 via the conductive bumps 255 by hot pressing or re-flowing.

Referring to FIG. 2E, a first dielectric layer 24 made of a polymer material such as epoxy resin or polyimide (PI) is filled between the sensor chips 25 on the light-permeable carrier board 20 to cover the metallic circuits 23 and peripheries of the sensor chips 25 without covering the sensing areas 253 of the sensor chips 25.

Referring to FIG. 2F, the first dielectric layer 24 is ground such that the first dielectric layer 24 is flush with the non-active surfaces of the sensor chips 25.

Referring to FIG. 2G, a second dielectric layer 26 made of a polymer material such as epoxy resin or polyimide is formed to cover the sensor chips 25 and the first dielectric layer 24.

Referring to FIG. 2H, through cutting, etching, plasma or laser processing, grooves 260 are formed between the sensor chips 25, penetrating the first and second dielectric layers 24 and 26 so as to expose the metallic circuits 23 on the light-permeable carrier board 20.

Referring to FIG. 2I, by using a redistribution layer (RDL) technique, a plurality of conductive traces 27 is formed on the second dielectric layer 26 and electrically connected to the metallic circuits 23 exposed from the first and second dielectric layers 24 and 26. The conductive traces 27 are made of Ti/Cu/Cu/Ni, Ti/Cu/Ni, TiW/Cu/Ni, Al/NiV/Cu, or TiW/Au.

Thereafter, the sensor chips 25 are singulated so as to form a plurality of sensor semiconductor devices.

Alternatively, referring to FIGS. 2J and 2K, after the conductive traces 27 are formed, a solder mask layer 28 is formed to cover the second dielectric layer 26 and the conductive traces 27, and a plurality of openings is formed in the solder mask layer 28 to expose a portion of the conductive traces 27 such that conductive elements 29 such as solder balls are mounted on the exposed conductive traces 27 for electrically connecting the sensor semiconductor devices to an external device.

In accordance with the above-described method, the present invention further provides a sensor semiconductor device, which comprises: a light-permeable carrier board 20; metallic circuits 23 formed on edges of the light-permeable carrier board 20; a sensor chip 25 having an active surface and a non-active surface opposed to the active surface, wherein the active surface has a sensing area 253 and a plurality bond pads 254 and conductive bumps are disposed on the bond pads 254 such that the sensor chip 25 can be mounted on the metallic circuits 23 through the conductive bumps 255; a first dielectric layer 24 covering sides of the sensor chip 25; a second dielectric layer 26 covering the non-active surface of the sensor chip 25; and conductive traces 27 formed on the first and second dielectric layers 24, 26 for electrically connecting the metallic circuits 23.

The sensor semiconductor device further comprises a solder mask layer 28 formed on the second dielectric layer 26 and the conductive traces 27, the solder mask layer having a plurality of openings formed to expose a portion of the conductive traces 27; and conductive elements 29 mounted on the exposed conductive traces 27.

### Second Preferred Embodiment

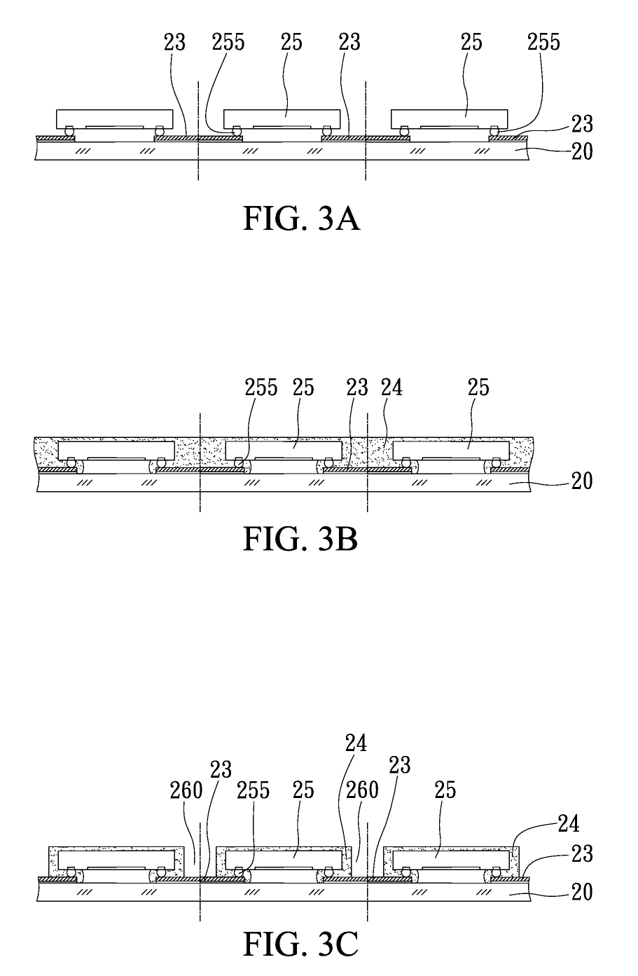

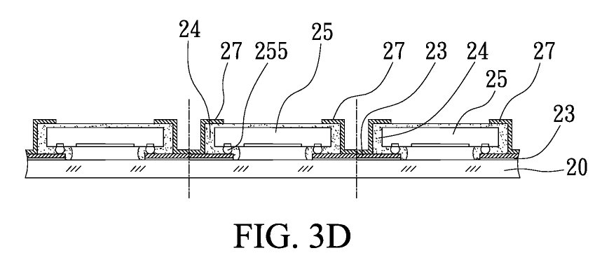

FIGS. 3A to 3D are schematic views showing the second preferred embodiment of a sensor semiconductor device and a manufacturing method thereof in accordance with the present invention. For purpose of simplification, elements same as or similar to those of the above-described embodiment are denoted by the same reference numerals.

The present embodiment is mostly similar to the first preferred embodiment, a main difference of the second embodiment from the first embodiment is a dielectric layer is directly formed on the light-permeable carrier board to cover the sensor chips and the metallic circuits and filled between the sensor chips, thereby eliminating the need of forming the second dielectric layer of the first embodiment.

Referring to FIG. 3A, a light-permeable carrier board 20 with a plurality of metallic circuits 23 is provided. Thinned and good sensor chips 25 are mounted on and electrically connected to the metallic circuits 23 of the light-permeable carrier board 20 via conductive bumps 255 of the sensor chips 25.

Referring to FIG. 3B, a dielectric layer 24 is directly formed on the light-permeable carrier board 20 to cover the sensor chips 25 and the metallic circuits 23 so as to dispenses with the steps of grinding a first dielectric layer and coating a second dielectric layer as in the first embodiment. The dielectric layer 24 is made of a polymer material such as epoxy resin or polyimide (PI), which is filled between the sensor chips 25 and covers the sensor chips 25.

Referring to FIG. 3C, through cutting, etching, plasma, or laser processing, grooves 260 are formed between the sensor chips 25, penetrating the dielectric layer 24 so as to expose the metallic circuits 23 on the light-permeable carrier board 20.

Referring to FIG. 3D, by using a redistribution layer (RDL) technique, a plurality of conductive traces 27 is formed on the dielectric layer 24 and electrically connected to the metallic circuits 23 exposed from the dielectric layer 24.

After the conductive traces are formed, a solder mask layer and conductive elements can further be formed on the dielectric layer. Thereafter, the sensor chips are singulated so as to form a plurality of sensor semiconductor devices. Therefore, the present invention mainly comprises: providing a light-permeable carrier board with a plurality of metallic circuits, and providing a plurality of sensor chips with bond pads, wherein conductive bumps are formed on the bond ponds, and the sensor chips are pre-thinned and pre-determined as good dies by chip probing (CP) so as to prevent chip damage caused by the conventional thinning process and allow the wafer to become thinner and meanwhile ensure the sensor chips in use are good dies, the sensor chips being electrically connected to the metallic circuits of the light-permeable carrier board via the conductive bumps; forming a first dielectric layer between the sensor chips on the light-permeable carrier board to cover peripheries of the sensor chips, forming a second dielectric layer to cover the sensor chips and the first dielectric layer, forming grooves in the first and second dielectric layers for exposing the metallic circuits on the light-permeable carrier board, and forming on the second dielectric layer a plurality of conductive traces electrical connecting the metallic circuits, or, alternatively, forming a dielectric layer on the light-permeable carrier board so as to dispense with the process of forming a second dielectric layer, the dielectric layer covering the sensor chips and metallic circuits and being filled between the sensor chips, forming grooves in the dielectric layer to expose the metallic circuits on the light-permeable carrier board, and forming on the dielectric layer a plurality of conductive traces for electrical connecting with the metallic circuits; disposing a solder mask layer and conductive elements on the dielectric layer, and singulating the sensor chips so as to form a plurality of sensor semiconductor devices. The present invention prevents breakage of trace connections due to a sharp angle formed at joints and overcomes poor electrical connection of traces and chip damage due to an alignment error in cutting a wafer from the back thereof, and also overcomes high fabrication cost caused by multiple sputtering processes for forming traces in the prior art.

### Third Preferred Embodiment

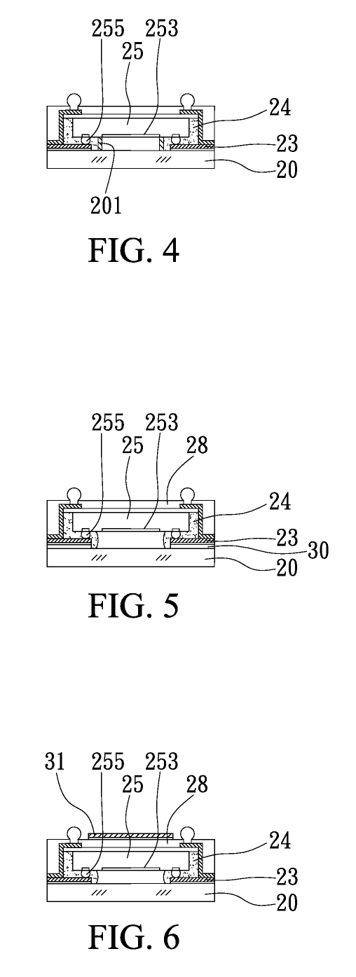

FIG. 4 is a schematic view showing the third preferred embodiment of a sensor semiconductor device and a manufacturing method thereof in accordance with the present invention. For purpose of simplification, elements same as or similar to those of the above-described embodiments are denoted by the same reference numerals.

The present embodiment is mostly similar to the above-described embodiments, a main difference of the present embodiment from the above-described embodiments is a dam structure 201 is pre-disposed on the light-permeable carrier board 20 corresponding in position to the peripheries of the sensor chips, so as to efficiently prevent the first dielectric layer 24 from covering the sensing areas 253 of the sensor chips 25 when the sensor chips 25 are mounted on the metallic circuits 23 via the conductive bumps 255 and the first dielectric layer 24 is filled between adjacent sensor chips 25.

### Fourth Preferred Embodiment

FIG. 5 is a schematic view showing the fourth preferred embodiment of a sensor semiconductor device and a manufacturing method thereof in accordance with the present invention. For purpose of simplification, elements same as or similar to those of the above-described embodiments are denoted by the same reference numerals.

The present embodiment is mostly similar to the above-described embodiments, a main difference of the present embodiment from the above-described embodiments is a buffer layer 30 made of such as polyimide (PI) is formed on the light-permeable carrier board 20 at predetermined positions and the metallic circuits 23 is formed on the buffer layer 30 so as to alleviate the stress of the metallic circuits 23. There is no buffer layer 30 formed on the light-permeable carrier board 20 at positions corresponding to the sensing areas 253 of the sensor chips 25.

### Fifth Preferred Embodiment

FIG. 6 is a schematic view showing the fifth preferred embodiment of a sensor semiconductor device and a manufacturing method thereof in accordance with the present invention. For purpose of simplification, elements same as or similar to those of the above-described embodiments are denoted by the same reference numerals.

The present embodiment is mostly similar to the above-described embodiments, a main difference of the present embodiment from the above-described embodiments is a reinforcing element 31 such as a dummy die or a glass is adhered to the solder mask layer 28 so as to reinforce the sensor semiconductor device.

### Sixth Preferred Embodiment

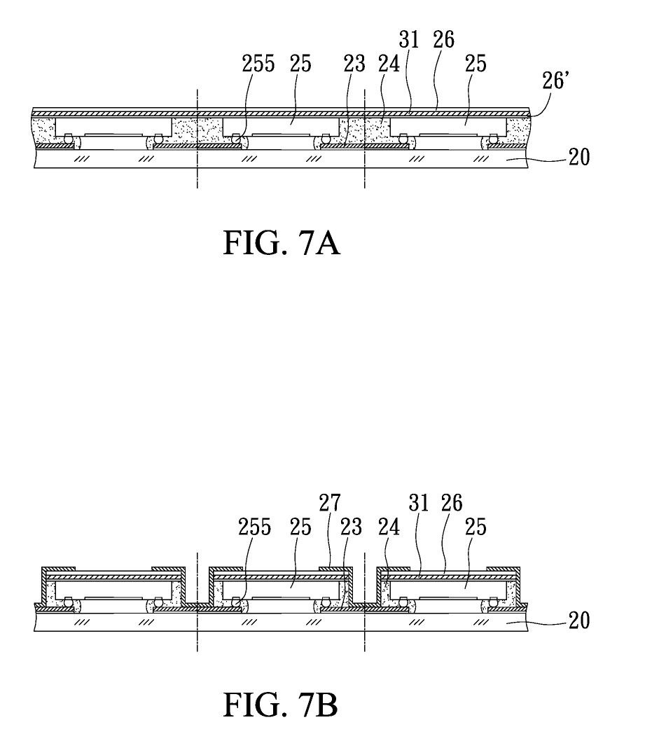

FIGS. 7A and 7B are schematic views showing the sixth preferred embodiment of a sensor semiconductor device and a manufacturing method thereof in accordance with the present invention. For purpose of simplification, elements same as or similar to those of the above-described embodiments are denoted by the same reference numerals.

The present embodiment is mostly similar to the above-described embodiments, a main difference of the present embodiment from the above-described embodiments is the present embodiment comprises the following steps: filling the first dielectric layer 24 between the sensor chips 25 and grinding the first dielectric layer 24 until the first dielectric layer 24 is flush with the non-active surfaces of the sensor chips 25; adhering a reinforcing element 31 such as a dummy die or glass to the sensor chips 25 and the first dielectric layer 24 through an adhesive 26′ so as to reinforce the semiconductor devices; covering the reinforcing element 31 with a second dielectric layer 26; forming grooves between the sensor chips 25, penetrating the second dielectric layer 26, the reinforcing element 31 and the first dielectric layer 24 so as to expose the metallic circuits 23 on the light-permeable carrier board 20; and forming on the second dielectric layer 26 the conductive traces 27 electrical connecting the metallic circuits 23.

Subsequent processes are similar to those of the above-described embodiments and detailed description thereof is omitted hereby.

The aforesaid embodiments merely serve as the preferred embodiments of the present invention. The aforesaid embodiments should not be construed as to limit the scope of the present invention in any way. Hence, many other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A manufacturing method of a sensor semiconductor device, comprising the steps of:
providing a light-permeable carrier board and a plurality of sensor chips, wherein the light-permeable carrier board has a plurality of metallic circuits formed thereon, the sensor chips each have an active surface and a non-active surface opposed to the active surface, the active surface has a sensing area disposed thereon and a plurality of bond pads disposed around the sensing area, and conductive bumps are formed on the bond pads such that the sensor chips are mounted on and electrically connected to the metallic circuits of the light-permeable carrier board via the conductive bumps;
filling a first dielectric layer between the sensor chips on the light-permeable carrier board so as to cover peripheries of the sensor chips and the metallic circuits;
covering the sensor chips and the first dielectric layer with a second dielectric layer, and forming grooves between the sensor chips, penetrating the first and second dielectric layers so as to expose the metallic circuits on the light-permeable carrier board;
forming a plurality of conductive traces on the second dielectric layer, and electrically connecting the conductive traces to the metallic circuits exposed from the first and second dielectric layers; and
singulating the sensor chips so as to form a plurality of sensor semiconductor devices.

2. The manufacturing method of claim 1, further comprising forming a solder mask layer to cover the second dielectric layer and the conductive traces, wherein the solder mask layer has a plurality of openings for exposing a portion of the conductive traces; and mounting conductive elements to the exposed conductive traces.

3. The manufacturing method of claim 2, further comprising adhering a reinforcing element to the solder mask layer.

4. The manufacturing method of claim 1, wherein the process for forming the metallic circuits on the light-permeable carrier board comprises the steps of:
forming a thin conductive layer on the light-permeable carrier board;
covering the thin conductive layer with a resist layer and forming openings in the resist layer for exposing a portion of the thin conductive layer;
forming the metallic circuits on the thin conductive layer in the openings by electroplating; and
removing the resist layer and the thin conductive layer covered by the resist layer.

5. The manufacturing method of claim 1, wherein the process for manufacturing the sensor chips comprises the steps of:
providing a wafer having a plurality of sensor chips, wherein the wafer and sensor chips each have an active surface and a non-active surface opposed to the active surface, the active surface of each of the sensor chips has a sensing area disposed thereon and a plurality of bond pads disposed around the sensing area;
after picking out good dies from the sensor chips by chip probing (CP), mounting conductive bumps on the bond pads of the good dies; and
thinning the non-active surface of the wafer and singulating the sensor chips so as to form a plurality of sensor chips with conductive bumps.

6. The manufacturing method of claim 1, wherein the light-permeable carrier board is divided into a plurality of carrier board units, and the metallic circuits are formed between adjacent carrier board units.

7. The manufacturing method of claim 1, wherein the first dielectric layer is filled between the sensor chips on the light-permeable carrier board and ground so as to be flush with the non-active surfaces of the sensor chips.

8. The manufacturing method of claim 1, wherein the conductive traces are formed on the second dielectric layer by a redistribution layer (RDL) technique.

9. The manufacturing method of claim 1, wherein a dam structure is pre-disposed on the light-permeable carrier board corresponding in position to the peripheries of the sensing area of the sensor chips.

10. The manufacturing method of claim 1, wherein a buffer layer is formed between the light-permeable carrier board and the metallic circuits.

11. The manufacturing method of claim 1, wherein a reinforcing element is adhered to the sensor chips and the first dielectric layer, and grooves are formed between the sensor chips, penetrating the second dielectric layer, the reinforcing element and the first dielectric layer for exposing the metallic circuits on the light-permeable carrier board such that the conductive traces electrically connected to the metallic circuits can be formed on the second dielectric layer.

12. A sensor semiconductor device, comprising:
a light-permeable carrier board;
metallic circuits formed on edges of the light-permeable carrier board;
a sensor chip having an active surface and a non-active surface opposed to the active surface, wherein the active surface is formed with a sensing area and a plurality of bond pads, and conductive bumps are formed on the bond pads such that the sensor chip can be mounted on the metallic circuits via the conductive bumps;
a first dielectric layer covering periphery of the sensor chip;
a second dielectric layer covering the non-active surface of the sensor chip; and
conductive traces formed on the first and second dielectric layers and electrically connected to the metallic circuits.

13. The sensor semiconductor device of claim 12, wherein a buffer layer is formed between the light-permeable carrier board and the metallic circuits.

14. The sensor semiconductor device of claim 12, wherein the sensor chip is thinned and determined as a good die by chip probing (CP).

15. The sensor semiconductor device of claim 12, wherein the non-active surface of the sensor chip is flush with the first dielectric layer.

16. The sensor semiconductor device of claim 12, further comprising: a solder mask layer formed on the second dielectric layer and conductive traces, wherein openings are formed in the solder mask layer for exposing a portion of the conductive traces; and conductive elements mounted on the exposed conductive traces.

17. The sensor semiconductor device of claim 16, wherein a reinforcing element is adhered to the solder mask layer.

18. The sensor semiconductor device of claim 12, wherein a reinforcing element is adhered to the sensor chip and the first dielectric layer.

19. The sensor semiconductor device of claim 12, wherein a dam structure is disposed on the light-permeable carrier board corresponding in position to the periphery of the sensing area of the sensor chip.

20. A manufacturing method of a sensor semiconductor device, comprising the steps of:
providing a light-permeable carrier board and a plurality of sensor chips, wherein the light-permeable carrier board has a plurality of metallic circuits formed thereon, the sensor chips each have an active surface and a non-active surface opposed to the active surface, the active surface has a sensing area and a plurality of bond pads disposed around the sensing area, conductive bumps are formed on the bond pads such that the sensor chips are mounted on and electrically connected to the metallic circuits of the light-permeable carrier board via the conductive bumps;
forming on the light-permeable carrier board a dielectric layer covering the sensor chips and the metallic circuits;
forming grooves between the sensor chips, penetrating the dielectric layer for exposing the metallic circuits on the light-permeable carrier board;
forming a plurality of conductive traces on the dielectric layer, and electrically connecting the conductive traces to the metallic circuits exposed from the dielectric layer; and
singualting the sensor chips so as to form a plurality of sensor semiconductor devices.

21. The manufacturing method claim 20, further comprising: forming a solder mask layer to cover the dielectric layer and the conductive traces, wherein the solder mask layer has openings to expose a portion of the conductive traces; and mounting conductive elements on the exposed conductive traces.

22. The manufacturing method of claim 21, further comprising adhering a reinforcing element to the solder mask layer.

23. The manufacturing method of claim 20, wherein the process for forming the metallic circuits on the light-permeable carrier board comprises the steps of:
forming a thin conductive layer on the light-permeable carrier board;
covering the thin conductive layer with a resist layer, and forming openings in the resist layer for exposing a portion of the thin conductive layer;
forming the metallic circuits on the thin conductive layer in the openings by electroplating; and
removing the resist layer and the thin conductive layer covered by the resist layer.

24. The manufacturing method claim 20, wherein the process for manufacturing the sensor chips comprises the steps of:
providing a wafer having a plurality of sensor chips, wherein the wafer and sensor chips each have an active surface and a non-active surface opposed to the active surface, the active surface of each of the sensor chips has a sensing area and a plurality of bond pads disposed around the sensing area;
after picking out good dies from the sensor chips by chip probing (CP), mounting conductive bumps on the bond pads of the good dies; and
thinning the non-active surface of the wafer and singulating the sensor chips so as to form a plurality of sensor chips with conductive bumps.

25. The manufacturing method of claim 20, wherein the light-permeable carrier board is divided into a plurality of carrier board units, and the metallic circuits are formed between adjacent carrier board units.

26. The manufacturing method of claim 20, wherein the conductive traces are formed on the dielectric layer by a redistribution layer (RDL) technique.

27. The manufacturing method of claim 20, wherein a dam structure is pre-disposed on the light-permeable carrier board corresponding in position to the periphery of the sensing area of each of the sensor chips.

28. The manufacturing method of claim 20, wherein a buffer layer is formed between the light-permeable carrier board and the metallic circuits.

29. A sensor semiconductor device, comprising:
a light-permeable carrier board;
metallic circuits formed on edges of the light-permeable carrier board;
a sensor chip having an active surface and a non-active surface opposed to the active surface, wherein the active surface is formed with a sensing area and a plurality of bond pads, and conductive bumps are formed on the bond pads such that the sensor chip is mounted on the metallic circuits via the conductive bumps;
a dielectric layer covering sides of the sensor chip and the non-active surface of the sensor chip; and
conductive traces formed on the dielectric layer and electrically connected to the metallic circuits.

30. The sensor semiconductor device of claim 29, wherein a buffer layer is formed between the light-permeable carrier board and the metallic circuits.

31. The sensor semiconductor device of claim 29, wherein the sensor chip is thinned and determined as a good die through chip probing (CP).

32. The sensor semiconductor device of claim 29, further comprising: a solder mask layer formed on the dielectric layer and the conductive traces, wherein openings are formed in the solder mask layer for exposing a portion of the conductive traces; and conductive elements mounted on the exposed conductive traces.

33. The sensor semiconductor device of claim 32, wherein a reinforcing element is adhered to the solder mask layer.

34. The sensor semiconductor device of claim 29, wherein a dam structure is disposed on the light-permeable carrier board corresponding in position to the periphery of the sensing area of the sensor chip.
